(19) United States
(12) Patent Application Publication
(10) Pub. No.: US 2022/0026335 A1
(43) Pub. Date: Jan. 27, 2022

(54) METHOD FOR OPERATING A SENSOR FOR DETECTING PARTICLES IN A MEASURING GAS

(71) Applicant: Robert Bosch GmbH, Stuttgart (DE)

(72) Inventor: Carolin Maria Schilling, Bad Schoenborn (DE)

(73) Assignee: Robert Bosch GmbH, Stuttgart (DE)

(21) Appl. No.: 17/299,603

(22) PCT Filed: Oct. 22, 2019
(86) PCT No.: PCT/EP2019/078670

§ 371 Date: Jun. 3, 2021

(51) Int. Cl. G01N 15/06; G01M 15/10; G01R 19/165; F02D 41/22

(52) U.S. Cl. CPC G01N 15/0656; G01M 15/102; G01N 2015/0046; F02D 41/222; G01R 19/16566

(57) ABSTRACT

A method for operating a sensor for detecting particles in a measuring gas. The sensor includes a sensor element having an electrically insulating element substrate, a first electrode, and a second electrode. The first electrode and the second electrode is situated at the electrically insulating element. The first electrode and the second electrode carry out a current and/or voltage measurement. The sensor is operated in at least one measuring phase during which a first voltage is applied to the first electrode and the second electrode. A second voltage is applied to the first and second electrode during a predetermined time period outside the measuring phase, the second voltage being lower than a decomposition voltage for water. The presence of water on the sensor element is inferred if the current and/or voltage measurement, with the second voltage being applied, yields a value which exceeds a threshold value for an electric current.

### BACKGROUND INFORMATION

Numerous methods and devices for detecting particles, such as soot or dust particles, are provided in the related art.

Without limiting further embodiments and applications, the present invention is described hereafter, in particular, with reference to sensors for detecting particles, in particular, soot particles, in an exhaust gas flow of an internal combustion engine.

It is conventional to measure a concentration of particles, such as soot or dust particles, in an exhaust gas with the aid of two electrodes, which are situated on a ceramic. This may take place, for example, by a measurement of the electrical resistance of the ceramic material separating the two electrodes. More precisely, the electric current which flows between the electrodes when a voltage is applied thereto is measured. Due to electrostatic forces, the soot particles accumulate between the electrodes and, over time, form electrically conductive bridges between the electrodes. The more of these bridges are present, the more the measured current rises. Thus, an increasing short circuit of the electrodes forms. The sensor element is periodically regenerated by being brought to at least 700° C. by an integrated heating element, whereby the soot accumulations burn off.

Such sensors are used, for example, in an exhaust tract of an internal combustion engine, such as a diesel-type combustion engine. These sensors are usually situated downstream from the exhaust valve or the soot particulate filter.

Despite the numerous advantages of the devices for detecting particles provided in the related art, these still have improvement potential. The ceramic sensor element is sensitive to incoming moisture or prone to hydrothermal aging. A wide variety of damaging mechanisms at the sensor element due to water or condensate occur, and a reliable detection of drying of the electrodes is not possible thus far.

### SUMMARY

In accordance with an example embodiment of the present invention, a method for operating a sensor for detecting particles, in particular, soot particles, is provided, which at least largely avoids the disadvantages of conventional operating methods and, in particular, makes it possible to detect moisture in the electrode area and not to be dependent only on the dew point end data input to infer moisture in the sensor element.

In a method according to an example embodiment of the present invention for operating a sensor for detecting particles, in particular, soot particles, in a measuring gas, in particular, in the exhaust gas of an internal combustion engine, the sensor including a sensor element, the sensor element including at least one electrically insulating element, a first electrode and a second electrode, the first electrode and the second electrode being situated at the electrically insulating element, the first electrode and the second electrode carry out a current and/or voltage measurement. The sensor is operated in at least one measuring phase. During the measuring phase, a first voltage is applied to the first electrode and the second electrode. During a predetermined time period outside the measuring phase, a second voltage is applied to the first electrode and the second electrode. The second voltage is lower than a decomposition voltage for water. In the process, the presence of water on the sensor element is inferred if the current and/or voltage measurement, with the second voltage being applied, yields a value which exceeds a threshold value for an electric current.

The operating strategy provided herein in accordance with an example embodiment of the present invention makes it possible to detect moisture which short-circuits the electrodes, and to thus prevent regeneration or the activation of the measuring voltage. Both moisture during the regeneration and the application of the measuring voltage to the moist sensor element would damage the sensor element. This would result in spalling and platinum embrittlement. In particular, the example method allows the determination of moisture whenever the sensor is not used for particulate measurement. The method is thus used, among other things, for active moisture determination at a sensor for particulate measurement.

In one refinement of the present invention, a regeneration of the sensor or a switch into the measuring phase is prevented if the current and/or voltage measurement, with the second voltage being applied, yields a value which exceeds a first threshold value for an electric current. If an electric current is measured as a result of the comparatively low second voltage, it is clear that the sensor is wetted by moisture, and a regeneration or measuring phase is prevented or blocked to protect the sensor element.

In one refinement of the present invention, a regeneration of the sensor or a switch into the measuring phase is enabled if the value of the current and/or voltage measurement, after exceeding the first threshold value, falls below a second threshold value for an electric current. The first threshold value and the second threshold value may differ from one another or be identical. If an electric current is measured as a result of the comparatively low second voltage, it is clear that the sensor is wetted by moisture, and, for the protection of the sensor element, a regeneration or measuring phase is enabled only after a decrease of the current at the electrodes. In this way, the electrodes may be additionally protected. By applying this very low voltage to the electrodes, it is prevented that the electrodes are damaged by electrolysis, and the electrodes are thus actively protected.

In one refinement of the present invention, a regeneration of the sensor or a switch into the measuring phase is enabled after a predetermined time after a fall below the second threshold value. One modification of the method thus provides waiting for a certain time after a current at the electrodes has decayed due to moisture, to also have moisture reliably removed from the deeper ceramic layers of the sensor element, before the sensor element is regenerated or subjected to measuring voltage.

In one refinement of the present invention, a regeneration of the sensor or a switch into the measuring phase is enabled if the sensor receives a dew point end release from the outside, preferably a control unit. In this way, the enabling for a regeneration of the sensor or a switch into the measuring phase only occurs if no moisture is detected (any longer) at the sensor element, and additionally a dew point end release is present.

In one refinement of the present invention, the sensor is heated during the predetermined time period outside the measuring phase. This heating is also referred to as protective heating. For the protection of the ceramic sensor element, the sensor is thus operated using a protective heating strategy to prevent further absorption of moisture and to dry the sensor element.

In one refinement of the present invention, the sensor is heated to a temperature whose level depends on the value of the current and/or voltage measurement, with the second voltage being applied. The level of the current during the application of the second voltage and during the protective heating is thus evaluated, and the protective heating temperature is adapted for more rapid drying of the sensor element or for gentler drying of the sensor element.

In one refinement of the present invention, the sensor is situated in an exhaust tract of an internal combustion engine, the predetermined time period outside the measuring phase being after a cold start of the internal combustion engine, in the case of a missing dew point end release from an engine control unit of the internal combustion engine and/or upon a shortfall of a predetermined temperature in the exhaust tract.

A further modification of the method in accordance with an example embodiment of the present invention provides to drastically lowering the protective heating temperature, down to the unheated state, and utilizing the inactive times of the sensor for subjecting the electrodes to 1 V, and to determine moisture in the exhaust tract based on the current flowing through, and making this additional information available to the engine control unit, or to determine the dew point end by measurement and not being dependent on models.

In one refinement of the present invention, the second voltage is a value in a range of 0.005 V to 1.2 V, and preferably 0.05 V to 1.0 V.

Furthermore, in accordance with an example embodiment of the present invention, a computer program is provided, which is configured to carry out every step of the method according to the present invention.

Furthermore, in accordance with an example embodiment of the present invention, an electronic memory medium is provided, on which such a computer program is stored.

Furthermore, in accordance with an example embodiment of the present invention, an electronic control unit is provided, which includes such an electronic memory medium.

Within the meaning of the present invention, a particle shall be understood to mean a particle, in particular, an electrically conductive particle, such as soot or dust particles.

Within the scope of the present invention, an electrode shall be understood to mean a component which is suitable for a current and/or voltage measurement. Within the scope of the present invention, the information ‘first and second electrodes’ is only used to representationally distinguish the electrodes, but is not intended to indicate a particular order or weighting of these components.

Within the scope of the present invention, the electrodes may be designed as interdigital electrodes. Within the scope of the present invention, interdigital electrodes shall be understood to mean electrodes which are situated in such a way that they engage one another, in particular, engage one another in a comb-shaped manner.

Within the scope of the present invention, a current and/or voltage measurement shall be understood to mean a measurement of an electric current and/or a voltage. The measurement takes place between two electrodes or an electrode and a reference potential. A particular voltage may be applied to the electrodes in the process, and a current flow between the electrodes may be measured, or an electric current may be applied to the electrodes, and a voltage between the electrodes may be measured. A current and/or voltage measurement may, in particular, be a resistance measurement, it being possible to measure a resistance of the configuration formed by the electrodes and the substrate. For example, a voltage-controlled or voltage-regulated measurement and/or a current-controlled and/or current-regulated measurement may take place. The application of the current and/or of the voltage may take place in the form of a continuous signal and/or also in the form of a pulsed signal. For example, a DC voltage and/or a direct current may be applied, and a current response or a voltage response may be detected. As an alternative, a pulsed voltage and/or a pulsed current may be applied, and a current response or a voltage response may be detected. Instead of the instantaneous current flow through the electrodes, it is also possible to use a resistance of the electrodes or its reciprocal value (=conductance value) as a measuring variable. It may also be useful to integrate a charge from an instantaneous current flow. Furthermore, it is possible to apply a high voltage to one electrode and to measure an electric current, such as for example a discharge current, at a counter electrode or an electrical ground.

Within the scope of the present invention, a measuring phase shall be understood to mean a time period in which a voltage or voltage form applied to the electrodes is selected in such a way that it allows the resistance, or the impedance, and thus the particle load of the sensor, to be determined as precisely as possible. The voltage during the measuring phase does not have be suitable or optimized for the collection of particles from the measuring gas.

Within the scope of the present invention, a substrate shall be understood to mean an object having a plate-shaped, cube-shaped, cuboid or any other geometric design, which includes at least one planar surface and is manufactured from a ceramic material, a metallic material, a semi-conductor material or combinations thereof.

Within the scope of the present invention, a decomposition voltage for water shall be understood to mean the minimum difference in the electrode potentials of the anode and the cathode which is required for carrying out an electrolysis of water. At this voltage, the decomposition of the electrolyte due to electric attractive forces begins, which act between the electrodes on the one hand, and the respective oppositely charged anions or cations on the other hand. Electrolysis refers to a process in which electric current enforces a redox reaction. An electrolysis requires a DC voltage source, which supplies the electrical energy and expedites the chemical reactions. A portion of the electrical energy is converted into chemical energy. The theoretical decomposition voltage for water is 1.23 V.

In accordance with the present invention, a voltage below the decomposition voltage of water is applied to the electrodes during the protective heating to detect moisture on the electrodes as a result of the short circuit due to water. If an electric current is measured as a result of this low voltage, it is clear that the sensor is wetted by moisture, and, for the protection of the sensor element, a regeneration or measuring phase is only enabled after a dew point release and a decrease of the current at the electrodes. In this way, the electrodes may be additionally protected. By applying this very low voltage to the electrodes, it is prevented that the electrodes are damaged by electrolysis, and the electrodes are thus actively protected.

### BRIEF DESCRIPTION OF THE DRAWINGS

Additional optional details and features of the present invention are derived from the following description of preferred exemplary embodiments, which are schematically shown in the figures.

FIG. 1 shows a top view onto a sensor for detecting particles according to one specific example embodiment of the present invention.

FIG. 2 shows a flowchart of a method for operating a sensor for detecting particles according to one specific example embodiment of the present invention.

### DETAILED DESCRIPTION OF EXAMPLE EMBODIMENTS

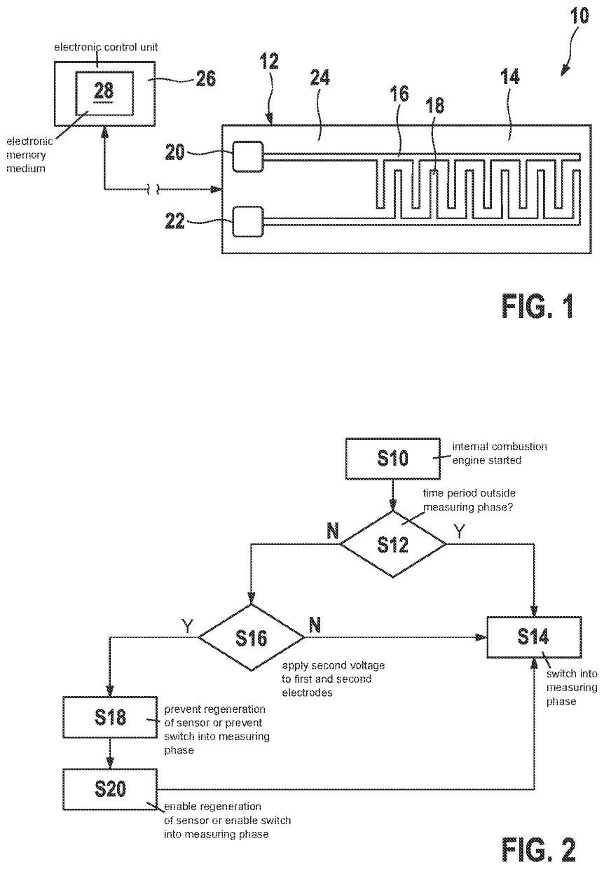

FIG. 1 shows a top view onto a sensor 10 for detecting particles in a measuring gas according to one specific embodiment of the present invention. Sensor 10 is designed, in particular, for detecting soot particles in a gas flow, such as an exhaust gas flow, of an internal combustion engine and for installation in an exhaust tract of a motor vehicle. Sensor 10 is designed as a soot sensor, for example, and may be situated downstream or upstream from a soot particulate filter of a motor vehicle including a diesel combustion engine. In the shown example, the measuring gas is exhaust gas of an internal combustion engine. In the shown exemplary embodiment, sensor 10 is designed as a resistive particle sensor.

Sensor 10 includes a sensor element 12. Sensor element 12 includes an electrically insulating element 14. Electrically insulating element 14 is a substrate. The substrate is a silicon wafer, for example. As an alternative, the substrate is manufactured from a ceramic material. Electrically insulating element 14 has an essentially cuboid design. Sensor element 10 furthermore includes a first electrode 16, a second electrode 18, a first feed line 20 and a second feed line 22. First electrode 16, second electrode 18, first feed line 20 and second feed line 22 are situated on an upper side 24 of substrate 14. First electrode 16 and second electrode 18 are designed as interdigital electrodes. First electrode 16 is connected to first feed line 20. Second electrode 18 is connected to second feed line 22. First feed line 20 and second feed line 22 represent connecting contacts, which are designed to electrically contact first electrode 16 and second electrode 18. First electrode 16 and second electrode 18 are designed to carry out a current and/or voltage measurement. Sensor 10 may optionally include further components, such as a protective tube and/or a heating element, which are not shown in greater detail. The sensor is operated in at least one measuring phase. During the measuring phase, a first voltage of 45 V, for example, is applied to first electrode 16 and second electrode 18. Sensor 10 is connected to an electronic control unit 26. Electronic control unit 26 is an engine control unit of the internal combustion engine, for example. The electronic control unit includes an electronic memory medium 28, such as a chip, on which a computer program is stored. The computer program includes instructions for carrying out a method for operating sensor 10. Such a method is described hereafter in greater detail.

FIG. 2 shows a flow chart of a method for operating a sensor 10 for detecting particles according to one specific embodiment of the present invention, such as that of sensor 10 shown in FIG. 1. In step S10, the internal combustion engine is started. In step S12, it is checked whether sensor 10 is in a time period outside the measuring phase. The time period outside the measuring phase is, for example, a cold start of the internal combustion engine, a missing dew point end release from an engine control unit of the internal combustion engine and/or upon a shortfall of a predetermined temperature in the exhaust tract. If the check in step S12 yields that it is not a cold start, a dew point end release is present and/or the predetermined temperature in the exhaust tract is exceeded, the presence of moisture at sensor element 12 may be excluded. In this case, the method proceeds to step S14 in which a switch into the measuring phase takes place.

If the check in step S12 yields that it is a cold start, a dew point end release is not present and/or the predetermined temperature in the exhaust tract falls short, a predetermined time period outside the measuring phase is determined, and the method proceeds to step S16. In step S16, a second voltage is applied to first electrode 16 and to second electrode 18 during the predetermined time period outside the measuring phase, the second voltage being lower than a decomposition voltage for water. The second voltage is a value in a range of 0.005 V to 1.2 V, and preferably 0.05 V to 1.0 V, for example 0.8 V or 1.0 V. In addition to potential enablings from outside sensor 10, a separate check of sensor 10 for the possible presence of water on sensor element 12 takes place. Sensor 10 is heated during the predetermined time period outside the measuring phase. If the current and/or voltage measurement, with the second voltage being applied, yields a value which exceeds a threshold value for an electric current, the presence of water on sensor element 12 is inferred. The first threshold value is 0 A, for example. If the current and/or voltage measurement, with the second voltage being applied, in step S16 yields a value which exceeds a first threshold value for an electric current, the method proceeds to step S18, and a regeneration of sensor 10 or a switch into the measuring phase is prevented. If the first threshold value is not exceeded, water or moisture may be excluded, and the method proceeds to step S14, and a switch into the measuring phase takes place. Subsequent to step S18, step S20 takes place, in which a regeneration of the sensor or a switch into the measuring phase is enabled if the value of the current and/or voltage measurement, after exceeding the first threshold value, falls below a second threshold value for an electric current. The second threshold value may be identical to the first threshold value or may differ therefrom. The enabling thus only occurs after the current at electrodes 16, 18 has decreased. The method then proceeds to step S14, and a switch into the measuring phase takes place.

The method may be modified as follows. A regeneration of sensor 10 or a switch into the measuring phase is enabled after a predetermined time after a fall below the second threshold value. In other words, a certain time is waited after a current at the electrodes has decayed due to moisture, to also have moisture reliably removed from the deeper ceramic layers of sensor element 12, before sensor element 12 is regenerated or subjected to a measuring voltage. A regeneration of sensor 10 or a switch into the measuring phase is enabled if, in addition to the decrease of the current at electrodes 16, 18, sensor 10 receives a dew point end release from the outside, such as for example the control unit 26. The sensor is heated to a temperature whose level depends on the value of the current and/or voltage measurement, with the second voltage being applied. In other words, the level of the current is evaluated by applying the second voltage during the protective heating, to adapt the protective heating temperature for more rapid drying of the sensor element or for gentler drying of the sensor element. A further modification of the method provides to drastically lowering the protective heating temperature, down to the unheated state, and to utilize the inactive times of the sensor for subjecting electrodes 16, 18 to 1 V, and to determine moisture in the exhaust tract based on the current flowing through, and to make this additional information available to the engine control unit, or to determine the dew point end by measurement and not being dependent on models.

1-12. (canceled)

13. A method for operating a sensor for detecting particles in a measuring gas, the sensor including a sensor element, the sensor element including at least one electrically insulating element, a first electrode, and a second electrode, the first electrode and the second electrode being situated at the electrically insulating element, the first electrode and the second electrode carrying out a current and/or voltage measurement, the method comprising the following steps:
operating the sensor in at least one measuring phase, a first voltage being applied to the first electrode and the second electrode during the measuring phase;
applying a second voltage to the first electrode and the second electrode during a predetermined time period outside the measuring phase, the second voltage being lower than a decomposition voltage for water; and
based on the current and/or voltage measurement, with the second voltage being applied, yielding a value which exceeds a threshold value for an electric current, inferring a presence of water on the sensor element.

14. The method as recited in claim 13, wherein the particles are soot particles, and the measuring gas in an exhaust gas of an internal combustion engine.

15. The method as recited in claim 13, further comprising:
preventing a regeneration of the sensor or preventing a switch into the measuring phase, based on the current and/or voltage measurement, with the second voltage being applied, yielding a value which exceeding a first threshold value for an electric current.

16. The method as recited in claim 15, wherein the regeneration of the sensor or the switch into the measuring phase is enabled when the value of the current and/or voltage measurement, after exceeding the first threshold value, falls below a second threshold value for an electric current.

17. The method as recited in claim 16, wherein the regeneration of the sensor or the switch into the measuring phase is enabled after a predetermined time after a fall below the second threshold value.

18. The method as recited in claim 15, wherein the regeneration of the sensor or the switch into the measuring phase is enabled based on the sensor receiving a dew point end release from outside the sensor.

19. The method as recited in claim 15, wherein the regeneration of the sensor or the switch into the measuring phase is enabled based on the sensor receiving a dew point end release from a control unit.

20. The method as recited in claim 13, wherein the sensor is heated during the predetermined time period outside the measuring phase.

21. The method as recited in claim 20, wherein the sensor is heated to a temperature whose level depends on the value of the current and/or voltage measurement, with the second voltage being applied.

22. The method as recited in claim 13, wherein the sensor is situated in an exhaust tract of an internal combustion engine, the predetermined time period outside the measuring phase being after a cold start of the internal combustion engine, in the case of a missing dew point end release from an engine control unit of the internal combustion engine and/or upon a shortfall of a predetermined temperature in the exhaust tract.

23. The method as recited in claim 13, wherein the second voltage is a value in a range of 0.005 V to 1.2 V.

24. The method as recited in claim 13, wherein the second voltage is a value in a range of 0.05 V to 1.0 V.

25. A non-transitory computer-readable medium on which is stored a computer program for operating a sensor for detecting particles in a measuring gas, the sensor including a sensor element, the sensor element including at least one electrically insulating element, a first electrode, and a second electrode, the first electrode and the second electrode being situated at the electrically insulating element, the first electrode and the second electrode carrying out a current and/or voltage measurement, the computer-program, when executed by a computer, causing the computer to perform the following steps:
operating the sensor in at least one measuring phase, a first voltage being applied to the first electrode and the second electrode during the measuring phase;
applying a second voltage to the first electrode and the second electrode during a predetermined time period outside the measuring phase, the second voltage being lower than a decomposition voltage for water; and
based on the current and/or voltage measurement, with the second voltage being applied, yielding a value which exceeds a threshold value for an electric current, inferring a presence of water on the sensor element.

26. An electronic memory medium on is stored a computer program for operating a sensor for detecting particles in a measuring gas, the sensor including a sensor element, the sensor element including at least one electrically insulating element, a first electrode, and a second electrode, the first electrode and the second electrode being situated at the electrically insulating element, the first electrode and the second electrode carrying out a current and/or voltage measurement, the computer-program, when executed by a computer, causing the computer to perform the following steps:
operating the sensor in at least one measuring phase, a first voltage being applied to the first electrode and the second electrode during the measuring phase;
applying a second voltage to the first electrode and the second electrode during a predetermined time period outside the measuring phase, the second voltage being lower than a decomposition voltage for water; and
based on the current and/or voltage measurement, with the second voltage being applied, yielding a value which exceeds a threshold value for an electric current, inferring a presence of water on the sensor element.

27. An electronic control unit configured to operate a sensor for detecting particles in a measuring gas, the sensor including a sensor element, the sensor element including at least one electrically insulating element, a first electrode, and a second electrode, the first electrode and the second electrode being situated at the electrically insulating element, the first electrode and the second electrode carrying out a current and/or voltage measurement, the electronic control unit configured to:
operate the sensor in at least one measuring phase, a first voltage being applied to the first electrode and the second electrode during the measuring phase;
apply a second voltage to the first electrode and the second electrode during a predetermined time period outside the measuring phase, the second voltage being lower than a decomposition voltage for water; and
based on the current and/or voltage measurement, with the second voltage being applied, yielding a value which exceeds a threshold value for an electric current, infer a presence of water on the sensor element.
